(19) United States
(12) Patent Application Publication
(10) Pub. No.: US 2025/0285289 A1
(43) Pub. Date: Sep. 11, 2025

(54) DETECTION OF CONNECTED SOLID REGIONS IN SOLID GEOMETRY OBJECTS

(71) Applicant: Roblox Corporation, San Mateo, CA (US)

(72) Inventors: Janos Michel Christoph MENY, San Mateo, CA (US); Mehdi RAHIMZADEH, San Mateo, CA (US); Thomas COOL, San Mateo, CA (US)

(73) Assignee: Roblox Corporation, San Mateo, CA (US)

(21) Appl. No.: 19/070,086

(22) Filed: Mar. 4, 2025

Related U.S. Application Data
(60) Provisional application No. 63/561,512, filed on Mar. 5, 2024.

(51) Int. Cl. G06T 7/187; G06T 17/10; G06T 17/20

(52) U.S. Cl. CPC G06T 7/187; G06T 17/10; G06T 17/20

(57) ABSTRACT

Implementations relate to methods, systems, and computer-readable media to detect connected solid regions in solid geometry objects. In some implementations, the method may include obtaining a mesh for a three-dimensional (3D) object, wherein the mesh includes a plurality of polygons, identifying, based on the plurality of polygons, connected components of the 3D object, determining, based on the connected components, two or more topologically interconnected sections of the 3D object, identifying a containment relationship between the two or more topologically interconnected sections of the 3D object, determining, based on the containment relationship, one or more distinct solid regions of the 3D object, determining an updated state of a first distinct solid region of the 3D object, wherein the updated state includes an updated position or an updated orientation, and causing the first distinct solid region of the 3D object in the updated state to be displayed within a virtual environment.

### CROSS-REFERENCE TO RELATED APPLICATIONS

This application claims priority to U.S. Provisional Application No. 63/561,512, entitled “DETECTION OF CONNECTED SOLID REGIONS IN SOLID GEOMETRY OBJECTS,” filed on Mar. 5, 2024, the content of which is incorporated herein in its entirety.

### TECHNICAL FIELD

Implementations relate generally to computer-based virtual experiences and computer graphics, and more particularly, to methods, systems, and computer readable media to detect connected solid regions in solid geometry objects.

### BACKGROUND

Some online virtual experience platforms allow users to connect with each other, interact with each other (e.g., within a virtual experience), create virtual experiences, and share information with each other via the Internet. Users of online virtual experience platforms may participate in multiplayer environments (e.g., in virtual three-dimensional environments), design custom environments, design characters, three-dimensional (3D) objects, and avatars, decorate avatars, and exchange virtual items/objects with other users.

Virtual environments commonly include complex three-dimensional (3D) objects. The capability to manipulate 3D objects in real time is an important aspect. Constructive Solid Geometry (CSG) operations, important in the creation and manipulation of complex shapes, involve the combination, subtraction, and/or intersection of solid objects. These operations are foundational to interactive design and simulation, providing the tools necessary to sculpt intricate and dynamic virtual environments.

When solid objects are combined or subtracted, the resulting geometry may include multiple, physically distinct regions. Traditional techniques to perform combination/subtraction operations often falter in accurately identifying and segregating such disconnected components, leading to inaccuracies that detract from the realism of the simulation of the 3D object in the virtual environment.

The background description provided herein is for the purpose of presenting the context of the disclosure. Work of the presently named inventors, to the extent it is described in this background section, as well as aspects of the description that may not otherwise qualify as prior art at the time of filing, are neither expressly nor impliedly admitted as prior art against the prior disclosure.

### SUMMARY

A system of one or more computers can be configured to perform particular operations or actions by virtue of having software, firmware, hardware, or a combination of them installed on the system that in operation causes the system to perform the actions. One or more computer programs can be configured to perform particular operations or actions by virtue of including instructions that, when executed by data processing apparatus, cause the apparatus to perform a computer-implemented method that includes obtaining a mesh for a three-dimensional (3D) object, wherein the mesh includes a plurality of polygons, identifying, based on the plurality of polygons, connected components of the 3D object, determining, based on the connected components, two or more topologically interconnected sections of the 3D object, identifying a containment relationship between the two or more topologically interconnected sections of the 3D object, and determining, based on the containment relationship, one or more distinct solid regions of the 3D object.

In some implementations, identifying the connected components may include performing mesh traversal of the mesh along polygon edges of the plurality of polygons to identify individual components of the 3D object, wherein the mesh traversal is performed by a breadth-first search (BFS) or a depth-first search (DFS). In some implementations, the computer-implemented method may further include storing the connected components in a disjoint-set data structure.

In some implementations, the computer-implemented method may further include determining whether each of the topologically interconnected sections is an inner shell or an outer shell. In some implementations determining whether each of the topologically interconnected sections is an inner shell or an outer shell may include determining a sign of an oriented volume corresponding to each topologically interconnected section.

In some implementations, each of the topologically interconnected sections is determined to be an outer shell, and the computer-implemented method may further include determining, in response to determination that each of the topologically interconnected sections is an outer shell, that each of the topologically interconnected sections is a distinct solid region distinct from other topologically interconnected sections.

In some implementations, the computer-implemented method may further include comprising determining a containment relationship between a first topologically interconnected section and a second topologically interconnected section based on a determination that a first bounding box that corresponds to the first topologically interconnected section is entirely contained within a second bounding box that corresponds to the second topologically interconnected section.

In some implementations, the first topologically interconnected section may be an inner shell that is enclosed only by the second topologically interconnected section that is an outer shell, and the computer-implemented method may further include determining that the first topologically interconnected section and the second topologically interconnected section correspond to a same distinct solid region.

In some implementations, the computer-implemented method may further include detecting a first distinct solid region based on identifying a first outer shell that contains a first inner shell. In some implementations, identifying the first outer shell that contains the first inner shell includes finding an outer shell that is closest to the inner shell, and wherein the outer shell has a winding number of +1 relative to the inner shell.

In some implementations, the computer-implemented method may further include providing identifying information of a first distinct solid region of the one or more distinct solid regions of the 3D object and a first sub-mesh associated with the first distinct solid region to a physics engine, determining an input state of the first distinct solid region of the 3D object, wherein the input state includes a position associated with the first distinct solid region of the 3D object, an orientation associated with the first distinct solid region of the 3D object, or a combination thereof, solving, by the physics engine, a set of equations based on the input state and the first sub-mesh associated with the first distinct solid region to determine an updated state of the first distinct solid region of the 3D object, wherein the updated state includes an updated position, an updated orientation, or a combination thereof, and causing the first distinct solid region of the 3D object in the updated state to be displayed.

One general aspect includes a non-transitory computer-readable medium with instructions stored thereon that when executed, performs operations that include obtaining a mesh for a three-dimensional (3D) object, wherein the mesh includes a plurality of polygons, identifying, based on the plurality of polygons, connected components of the 3D object, determining, based on the connected components, two or more topologically interconnected sections of the 3D object, identifying a containment relationship between the two or more topologically interconnected sections of the 3D object, and determining, based on the containment relationship, one or more distinct solid regions of the 3D object.

One general aspect includes a system that includes a memory with instructions stored thereon; and a processing device coupled to the memory, the processing device configured to access the memory and execute the instructions, where the execution of the instructions cause the processing device to perform operations that may include obtaining a mesh for a three-dimensional (3D) object, wherein the mesh includes a plurality of polygons, identifying, based on the plurality of polygons, connected components of the 3D object, determining, based on the connected components, two or more topologically interconnected sections of the 3D object, identifying a containment relationship between the two or more topologically interconnected sections of the 3D object, and determining, based on the containment relationship, one or more distinct solid regions of the 3D object.

### BRIEF DESCRIPTION OF THE DRAWINGS

FIG. 1 is a diagram of an example environment to detect connected solid regions in solid geometry objects to be rendered on a computing device, in accordance with some implementations.

FIG. 2A illustrates example images that depict simulations of erroneously identified disconnected components of a solid body, in accordance with some implementations.

FIG. 2B depicts an example solid body object that is represented by a plurality of polygons, in accordance with some implementations.

FIG. 3 illustrates an example method to detect connected solid regions in a solid geometry object to be rendered on a computing device, in accordance with some implementations.

FIG. 4 illustrates determination of whether a topologically interconnected section is an inner shell or an outer shell, in accordance with some implementations.

FIG. 5 depicts bounding box filtering to determine containment relationships between respective inner shells and outer shells, in accordance with some implementations.

FIG. 6 depicts an example of two solid bodies that are composed of two inner shells and two outer shells, in accordance with some implementations.

FIG. 7A depicts an example of determination of an outer shell that corresponds to a particular inner shell based on a winding number test, in accordance with some implementations.

FIG. 7B depicts another example of determination of an outer shell that corresponds to a particular inner shell based on a winding number test, in accordance with some implementations.

FIG. 7C depicts another example of determination of an outer shell that corresponds to a particular inner shell based on a winding number test, in accordance with some implementations.

FIG. 8A depicts detection of connected solid regions in an example solid geometry object, in accordance with some implementations.

FIG. 8B depicts an example workflow to provide a virtual experience simulation engine with a set of disconnected solid regions based on a solid body object generated from performing constructive solid geometry (CSG) operations, in accordance with some implementations.

FIG. 9 illustrates example images that depict simulations that include correctly identified disconnected components of a solid body, in accordance with some implementations.

FIG. 10 illustrates an example computing device, in accordance with some implementations.

### DETAILED DESCRIPTION

In the following detailed description, reference is made to the accompanying drawings, which form a part hereof. In the drawings, similar symbols typically identify similar components, unless context dictates otherwise. The illustrative implementations described in the detailed description, drawings, and claims are not meant to be limiting. Other implementations may be utilized, and other changes may be made, without departing from the spirit or scope of the subject matter presented herein. Aspects of the present disclosure, as generally described herein, and illustrated in the Figures, can be arranged, substituted, combined, separated, and designed in a wide variety of different configurations, all of which are contemplated herein.

References in the specification to “some implementations”, “an implementation”, “an example implementation”, etc. indicate that the implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, such feature, structure, or characteristic may be effected in connection with other implementations whether or not explicitly described.

Online virtual experience platforms (also referred to as “user-generated content platforms” or “user-generated content systems”) offer a variety of ways for users to interact with one another. For example, users of an online virtual experience platform may work together towards a common goal, share various virtual experience items, send electronic messages to one another, and so forth. Users of an online virtual experience platform may join virtual experience(s), e.g., games or other experiences as virtual characters, playing specific roles. For example, a virtual character may be part of a team or multiplayer environment wherein each character is assigned a certain role and has associated parameters, e.g., clothing, armor, weaponry, skills, etc. that correspond to the role. In another example, a virtual character may be joined by computer-generated characters, e.g., when a single player is part of a game.

A virtual experience platform may enable users (developers) of the platform to create objects, new games, and/or characters. For example, users of the online gaming platform may be enabled to create, design, and/or customize new characters (avatars), new animation packages, new three-dimensional objects, etc. and make them available to other users.

On some virtual platforms, developer users may generate and/or upload three-dimensional (3D) models of 3D objects, e.g., virtual characters or avatars, terrains, mechanisms, accessories, etc. The 3D objects may be made available for use in a virtual experience and for trade, barter, or sale on an online marketplace. The 3D models may be utilized and/or modified by other users. These objects may be viewed by one or more users within a virtual environment supported by the virtual experience platform. For example, motion of such 3D objects within the virtual environment may be displayed on user devices.

In some implementations, the 3D object may be associated with a model that includes a 3D mesh that represents the geometry of the object and includes vertices and defines edges and faces. The model may additionally include UV maps and/or textures that define properties of a surface of the 3D objects, e.g., a design on a surface, skin complexion, tattoos, etc.

A virtual experience platform may also enable developers (creators) to generate 3D objects based on performing constructive solid geometry (CSG) operations. CSG operations can enable creation of complex surfaces and/or objects by applying Boolean operators to combine simpler objects as well as by the removal of portions of an existing 3D object.

In some implementations, the CSG operations may be performed in an offline setting whereby a creator generates a 3D object using CSG operations and then uploads it to a virtual experience platform for use in a virtual environment. In some other implementations, a 3D object may be generated in real-time within a virtual experience or creator studio environment based on CSG operations applied to a 3D object.

A technical objective in computer graphics, particularly within virtual experience platforms, is realistic depiction of the physical behavior of 3D objects. A challenge in computer graphics and virtual experience (e.g., game) design, is to detect connected bodies in 3D objects that are generated based on CSG operations. In many scenarios, content creators (developers) may start with a mesh of an original 3D object and perform one or more Boolean operations that result in the generation of a new 3D object.

However, the newly generated 3D object may have artefacts from the application of CSG operations and may not accurately represent any portions of the 3D object that are no longer connected to the original 3D object. Simulation of the newly generated 3D object may consequently be erroneous and thereby provide an insufficiently immersive experience.

For superior user experience, it is important that connected portions of a 3D object are correctly identified (detected) and simulated, e.g., by a physics engine or physics solver. An objective of a virtual experience platform provider is the provision of realistic depiction of 3D objects, and particularly the physical behavior of the 3D objects. An additional objective is to provide tools to content creators that can enable them to generate custom 3D objects.

A technical problem is the provision of automatic, accurate, scalable, cost-effective, and reliable tools for creation (generation) and editing of solid body (3D) objects. Techniques described herein may be utilized to provide a scalable and adaptive technical solution for the accurate detection of connected portions of a solid body object.

Techniques described herein can be utilized to algorithmically determine disconnected parts of a solid body object in a physically accurate manner. By analyzing a polygonal mesh (e.g., triangle-based mesh, triangle and quad based mesh, etc.) that defines the solid body object (3D object) involved in CSG operations, the techniques can be utilized to discern and categorize solid regions, effectively handling disconnected geometry. This enables the precise splitting of objects into their constituent parts, ensuring that each is computed and manipulated based on its unique physical properties.

The techniques utilize a structured approach to compute physically accurate connected solid regions based on a provided solid body object that can be further utilized for other operations, e.g., additional CSG operations, physics simulations, rendering on a display device, etc. The various operations in detection of the connected solid regions include:

### Identification of Connected Components

Based on a received solid body object that is defined by a mesh that includes a set of polygons, at a first stage connected components are identified in the mesh. In some implementations, a disjointed set data structure may be utilized to pinpoint distinct topologically interconnected sections within the mesh.

### Computation of Winding Numbers

Subsequent to identifying the connected components, at a second stage, ray segment tracing may be utilized to compute a winding number for each connected component relative to every other component. The winding number serves as a metric that facilitates computation of containment relationships between different connected components.

### Recursive Selection and Grouping of Solid Regions

Based on the winding numbers determined for each connected component relative to every other component, recursive selection of the outermost component is performed and the winding number utilized to determine all other components that belong to the same solid region.

Enhanced Computational Efficiency through Early Out Heuristics

Per techniques of this disclosure, heuristics can be applied for early termination (early outs) of computations, which utilize the oriented volumes of connected components. These early outs can significantly speed up the detection of disconnected solid components in many scenarios, thereby enhancing overall performance.

### Preservation of Vertex Properties

Through each stage of the detection of connected solid regions, vertex properties of the vertices in the mesh are tracked, e.g., associated normals, UV coordinates, UV maps, etc., thereby ensuring the correct preservation of these attributes in each of the output meshes of the distinct solid regions.

Techniques described herein introduce a new approach to the detection of connected regions within a solid object body mesh that can enable users to create a wide variety of 3D objects that can be subjected to simulation (e.g., physics simulation that simulates object motion, rotation, etc.). The automated processes contribute to efficient and accessible 3D mesh customization of 3D objects, promoting creativity and enabling a wider range of users to create solid body objects with ease.

In virtual experience platforms that support user generated content (UGC), where user-generated content contributes to the platform, techniques disclosed herein can be deployed to empower creators to intricately craft and adapt complex, interactive, and realistic 3D environments on-the-fly. By enabling CSG operations that mimic physics accurately, design of immersive experiences with enhanced realism is enabled. This further enables greater user engagement and encourages a creative, dynamic online community, making CSG a critical tool for generation of solid body objects for use in virtual experiences.

In some implementations, the techniques may be utilized within a tool, e.g., a studio environment, which may be utilized by developers to generate 3D mesh assets that have been generated based on application of CSG operations. In some implementations, the 3D objects may be generated based on CSG operations derived from descriptions, e.g., textual prompts, voice prompts, sketches, etc., provided by users (e.g., developers or creator users). In some implementations, the tool may support creators to create accessories, e.g., for virtual characters where the 3D models (e.g., 3D meshes) have been created by the user, virtual characters (3D meshes) provided via the virtual experience platform, 3D meshes of 3D objects obtained or purchased from other users, 3D terrains and landscapes for use in the virtual experience, 3D objects such as buildings, etc.

In some implementations, the techniques described herein may be implemented on a virtual experience platform to enable users to modify 3D objects by applying CSG operations in real-time during their participation in a virtual experience. This can enable in-experience creation wherein users (e.g., non-developer users) can utilize the techniques to customize 3D objects for their virtual experience.

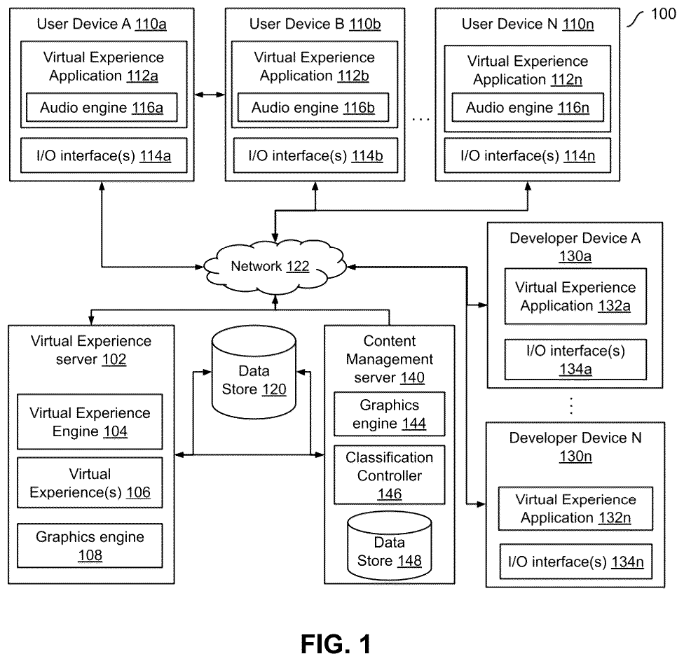

FIG. 1 is a diagram of an example environment to detect connected solid regions in solid geometry objects to be rendered on a computing device, in accordance with some implementations.

FIG. 1 and other figures use like reference numerals to identify like elements. A letter after a reference numeral, such as “110,” indicates that the text refers specifically to the element having that particular reference numeral. A reference numeral in the text without a following letter, such as “110,” refers to any or all of the elements in the figures bearing that reference numeral (e.g. “110” in the text refers to reference numerals “110a,” “110b,” and/or “110n” in the figures).

The system architecture 100 (also referred to as “system” herein) includes online virtual experience server 102, data store 120, user devices 110a, 110b, and 110n (generally referred to as “user device(s) 110” herein), and developer devices 130a and 130n (generally referred to as “developer device(s) 130” herein), virtual experience server 102, content management server 140, data store 120, user devices 110, and developer devices 130 are coupled via network 122. In some implementations, user devices(s) 110 and developer device(s) 130 may refer to the same or same type of device.

Online virtual experience server 102 can include a virtual experience engine 104, one or more virtual experience(s) 106, and graphics engine 108. A user device 110 can include a virtual experience application 112, and input/output (I/O) interfaces 114 (e.g., input/output devices). The input/output devices can include one or more of a microphone, speakers, headphones, display device, mouse, keyboard, game controller, touchscreen, virtual reality consoles, etc. The input/output devices can also include accessory devices that are connected to the user device by means of a cable (wired) or that are wirelessly connected.

Content management server 140 can include a graphics engine 144, and a classification controller 146. In some implementations, the content management server may include a plurality of servers. In some implementations, the plurality of servers may be arranged in a hierarchy, e.g., based on respective prioritization values assigned to content sources.

Graphics engine 144 may be utilized for the rendering of one or more objects, e.g., 3D objects associated with the virtual environment. Classification controller 146 may be utilized to classify assets such as 3D objects and for the detection of inauthentic digital assets, etc. Data store 148 may be utilized to store a search index, model information, etc.

A developer device 130 can include a virtual experience application 132, and input/output (I/O) interfaces 134 (e.g., input/output devices). The input/output devices can include one or more of a microphone, speakers, headphones, display device, mouse, keyboard, game controller, touchscreen, virtual reality consoles, etc.

System architecture 100 is provided for illustration. In different implementations, the system architecture 100 may include the same, fewer, more, or different elements configured in the same or different manner as that shown in FIG. 1.

In some implementations, network 122 may include a public network (e.g., the Internet), a private network (e.g., a local area network (LAN) or wide area network (WAN)), a wired network (e.g., Ethernet network), a wireless network (e.g., an 802.11 network, a Wi-Fi® network, or wireless LAN (WLAN)), a cellular network (e.g., a 5G network, a Long Term Evolution (LTE) network, etc.), routers, hubs, switches, server computers, or a combination thereof.

In some implementations, the data store 120 may be a non-transitory computer readable memory (e.g., random access memory), a cache, a drive (e.g., a hard drive), a flash drive, a database system, a cloud storage system, or another type of component or device capable of storing data. The data store 120 may also include multiple storage components (e.g., multiple drives or multiple databases) that may also span multiple computing devices (e.g., multiple server computers).

In some implementations, the online virtual experience server 102 can include a server having one or more computing devices (e.g., a cloud computing system, a rackmount server, a server computer, cluster of physical servers, etc.). In some implementations, the online virtual experience server 102 may be an independent system, may include multiple servers, or be part of another system or server.

In some implementations, the online virtual experience server 102 may include one or more computing devices (such as a rackmount server, a router computer, a server computer, a personal computer, a mainframe computer, a laptop computer, a tablet computer, a desktop computer, a distributed computing system, a cloud computing system, etc.), data stores (e.g., hard disks, memories, databases), networks, software components, and/or hardware components that may be used to perform operations on the online virtual experience server 102 and to provide a user with access to online virtual experience server 102. The online virtual experience server 102 may also include a website (e.g., a web page) or application back-end software that may be used to provide a user with access to content provided by online virtual experience server 102. For example, users may access online virtual experience server 102 using the virtual experience application 112 on user devices 110.

In some implementations, online virtual experience server 102 may be a type of social network providing connections between users or a type of user-generated content system that allows users (e.g., end-users or consumers) to communicate with other users on the online virtual experience server 102, where the communication may include voice chat (e.g., synchronous and/or asynchronous voice communication), video chat (e.g., synchronous and/or asynchronous video communication), or text chat (e.g., synchronous and/or asynchronous text-based communication). In some implementations of the disclosure, a “user” may be represented as a single individual. However, other implementations of the disclosure encompass a “user” (e.g., creating user) being an entity controlled by a set of users or an automated source. For example, a set of individual users federated as a community or group in a user-generated content system may be considered a “user.”

In some implementations, online virtual experience server 102 may be an online gaming server. For example, the virtual experience server may provide single-player or multiplayer games to a community of users that may access or interact with games using user devices 110 via network 122. In some implementations, games (also referred to as “video game,” “online game,” or “virtual game” herein) may be two-dimensional (2D) games, three-dimensional (3D) games (e.g., 3D user-generated games), virtual reality (VR) games, or augmented reality (AR) games, for example. In some implementations, users may participate in gameplay with other users. In some implementations, a game may be played in real-time with other users of the game.

In some implementations, gameplay may refer to the interaction of one or more players using user devices (e.g., 110) within a game (e.g., game that is part of virtual experience 106) or the presentation of the interaction on a display or other output device (e.g., 114) of a user device 110.

In some implementations, a virtual experience 106 can include an electronic file that can be executed or loaded using software, firmware or hardware configured to present the game content (e.g., digital media item) to an entity. In some implementations, a virtual experience application 112 may be executed and a virtual experience 106 executed in connection with a virtual experience engine 104. In some implementations, a virtual experience 106 such as a game may have a common set of rules or common goal, and the environment of a virtual experience 106 shares the common set of rules or common goal. In some implementations, different games may have different rules or goals from one another.

In some implementations, virtual experience(s) may have one or more environments (also referred to as “gaming environments” or “virtual environments” herein) where multiple environments may be linked. An example of an environment may be a three-dimensional (3D) environment. The one or more environments of a virtual experience application 112 may be collectively referred to a “world” or “gaming world” or “virtual world” or “universe” herein. An example of a world may be a 3D world of a virtual experience 106. For example, a user may build a virtual environment that is linked to another virtual environment created by another user. A character of the virtual game may cross the virtual border to enter the adjacent virtual environment.

It may be noted that 3D environments or 3D worlds use graphics that use a three-dimensional representation of geometric data representative of game content (or at least present game content to appear as 3D content whether or not 3D representation of geometric data is used). 2D environments or 2D worlds use graphics that use two-dimensional representation of geometric data representative of game content.

In some implementations, the online virtual experience server 102 can host one or more virtual experiences 106 and can permit users to interact with the virtual experience 106 using a virtual experience application 112 of user devices 110. Users of the online virtual experience server 102 may play, create, interact with, or build virtual experiences 106, communicate with other users, and/or create and build objects (e.g., also referred to as “item(s)” or “game objects” or “virtual game item(s)” herein) of virtual experiences 106. For example, in generating user-generated virtual items, users may create characters, decoration for the characters, one or more virtual environments for an interactive game, or build structures used in a game. In some implementations, users may buy, sell, or trade virtual game objects, such as in-platform currency (e.g., virtual currency), with other users of the online virtual experience server 102. In some implementations, online virtual experience server 102 may transmit game content to virtual experience applications (e.g., 112). In some implementations, game content (also referred to as “content” herein) may refer to any data or software instructions (e.g., game objects, game, user information, video, images, commands, media item, etc.) associated with online virtual experience server 102 or virtual experience applications. In some implementations, game objects (e.g., also referred to as “item(s)” or “objects” or “virtual objects” or “virtual game item(s)” herein) may refer to objects that are used, created, shared or otherwise depicted in virtual experiences 106 of the online virtual experience server 102 or virtual experience applications 112 of the user devices 110. For example, game objects may include a part, model, character, accessories, tools, weapons, clothing, buildings, vehicles, currency, flora, fauna, components of the aforementioned (e.g., windows of a building), and so forth.

It may be noted that the online virtual experience server 102 hosting virtual experiences 106, is provided for purposes of illustration, rather than limitation. In some implementations, online virtual experience server 102 may host one or more media items that can include communication messages from one user to one or more other users. Media items can include, but are not limited to, digital video, digital movies, digital photos, digital music, audio content, melodies, website content, social media updates, electronic books, electronic magazines, digital newspapers, digital audio books, electronic journals, web blogs, real simple syndication (RSS) feeds, electronic comic books, software applications, etc. In some implementations, a media item may be an electronic file that can be executed or loaded using software, firmware or hardware configured to present the digital media item to an entity.

In some implementations, a virtual application 106 may be associated with a particular user or a particular group of users (e.g., a private game), or made widely available to users with access to the online virtual experience server 102 (e.g., a public game). In some implementations, where online virtual experience server 102 associates one or more virtual experiences 106 with a specific user or group of users, online virtual experience server 102 may associate the specific user(s) with a virtual experience 106 using user account information (e.g., a user account identifier such as username and password).

In some implementations, online virtual experience server 102 or user devices 110 may include a virtual experience engine 104 or virtual experience application 112. In some implementations, virtual experience engine 104 may be used for the development or execution of virtual experiences 106. For example, virtual experience engine 104 may include a rendering engine (“renderer”) for 2D, 3D, VR, or AR graphics, a physics engine, a collision detection engine (and collision response), sound engine, scripting functionality, animation engine, artificial intelligence engine, networking functionality, streaming functionality, memory management functionality, threading functionality, scene graph functionality, or video support for cinematics, among other features. The components of the virtual experience engine 104 may generate commands that help compute and render the game (e.g., rendering commands, collision commands, physics commands, etc.) In some implementations, virtual experience applications 112 of user devices 110, may work independently, in collaboration with virtual experience engine 104 of online virtual experience server 102, or a combination of both.

In some implementations, both the online virtual experience server 102 and user devices 110 may execute a virtual experience engine and a virtual experience application (104 and 112, respectively). The online virtual experience server 102 using virtual experience engine 104 may perform some or all the virtual experience engine functions (e.g., generate physics commands, rendering commands, etc.), or offload some or all the virtual experience engine functions to virtual experience engine 104 of user device 110. In some implementations, each virtual application 106 may have a different ratio between the virtual experience engine functions that are performed on the online virtual experience server 102 and the virtual experience engine functions that are performed on the user devices 110. For example, the virtual experience engine 104 of the online virtual experience server 102 may be used to generate physics commands in cases where there is a collision between at least two virtual application objects, while the additional virtual experience engine functionality (e.g., generate rendering commands) may be offloaded to the user device 110. In some implementations, the ratio of virtual experience engine functions performed on the online virtual experience server 102 and user device 110 may be changed (e.g., dynamically) based on gameplay conditions. For example, if the number of users participating in gameplay of a particular virtual application 106 exceeds a threshold number, the online virtual experience server 102 may perform one or more virtual experience engine functions that were previously performed by the user devices 110.

For example, users may be playing a virtual application 106 on user devices 110, and may send control instructions (e.g., user inputs, such as right, left, up, down, user election, or character position and velocity information, etc.) to the online virtual experience server 102. Subsequent to receiving control instructions from the user devices 110, the online virtual experience server 102 may send gameplay instructions (e.g., position and velocity information of the characters participating in the group gameplay or commands, such as rendering commands, collision commands, etc.) to the user devices 110 based on control instructions. For instance, the online virtual experience server 102 may perform one or more logical operations (e.g., using virtual experience engine 104) on the control instructions to generate gameplay instruction(s) for the user devices 110. In other instances, online virtual experience server 102 may pass one or more or the control instructions from one user device 110 to other user devices (e.g., from user device 110a to user device 110b) participating in the virtual application 106. The user devices 110 may use the gameplay instructions and render the gameplay for presentation on the displays of user devices 110.

In some implementations, the control instructions may refer to instructions that are indicative of in-game actions of a user's character. For example, control instructions may include user input to control the in-game action, such as right, left, up, down, user selection, gyroscope position and orientation data, force sensor data, etc. The control instructions may include character position and velocity information. In some implementations, the control instructions are sent directly to the online virtual experience server 102. In other implementations, the control instructions may be sent from a user device 110 to another user device (e.g., from user device 110b to user device 110n), where the other user device generates gameplay instructions using the local virtual experience engine 104. The control instructions may include instructions to play a voice communication message or other sounds from another user on an audio device (e.g., speakers, headphones, etc.), for example voice communications or other sounds generated using the audio spatialization techniques as described herein.

In some implementations, gameplay instructions may refer to instructions that allow a user device 110 to render gameplay of a game, such as a multiplayer game. The gameplay instructions may include one or more of user input (e.g., control instructions), character position and velocity information, or commands (e.g., physics commands, rendering commands, collision commands, etc.).

In some implementations, the online virtual experience server 102 may store characters created by users in the data store 120. In some implementations, the online virtual experience server 102 maintains a character catalog and game catalog that may be presented to users. In some implementations, the game catalog includes images of virtual experiences stored on the online virtual experience server 102. In addition, a user may select a character (e.g., a character created by the user or other user) from the character catalog to participate in the chosen game. The character catalog includes images of characters stored on the online virtual experience server 102. In some implementations, one or more of the characters in the character catalog may have been created or customized by the user. In some implementations, the chosen character may have character settings defining one or more of the components of the character.

In some implementations, a user's character can include a configuration of components, where the configuration and appearance of components and more generally the appearance of the character may be defined by character settings. In some implementations, the character settings of a user's character may at least in part be chosen by the user. In other implementations, a user may choose a character with default character settings or character setting chosen by other users. For example, a user may choose a default character from a character catalog that has predefined character settings, and the user may further customize the default character by changing some of the character settings (e.g., adding a shirt with a customized logo). The character settings may be associated with a particular character by the online virtual experience server 102.

In some implementations, the virtual experience platform may support three-dimensional (3D) objects that are represented by a 3D model and includes a surface representation used to draw the character or object (also known as a skin or mesh) and a hierarchical set of interconnected bones (also known as a skeleton or rig). The rig may be utilized to animate the object and to simulate motion of the object. The 3D model may be represented as a data structure, and one or more parameters of the data structure may be modified to change various properties of the character, e.g., dimensions (height, width, girth, etc.); shape; movement style; number/type of parts; proportion, etc.

In some implementations, the 3D model may include a 3D mesh. The 3D mesh may define a three-dimensional structure of the unauthenticated virtual 3D object. In some implementations, the 3D mesh may also define one or more surfaces of the 3D object. In some implementations, the 3D object may be a virtual avatar, e.g., a virtual character such as a humanoid character, an animal-character, a robot-character, etc.

In some implementations, the mesh may be received (imported) in an FBX file format. The mesh file includes data that provides dimensional data about polygons that comprise the virtual 3D object and UV map data that describes how to attach portions of texture to various polygons that comprise the 3D object. In some implementations, the 3D object may correspond to an accessory, e.g., a hat, a weapon, a piece of clothing, etc. worn by a virtual avatar or otherwise depicted with reference to a virtual avatar.

In some implementations, a platform may enable users to submit (upload) candidate 3D objects for utilization on the platform. A virtual experience development environment (developer tool) may be provided by the platform, in accordance with some implementations. The virtual experience development environment may provide a user interface that enables a developer user to design and/or create virtual experiences, e.g., games. The virtual experience development environment may be a client-based tool (e.g., downloaded and installed on a client device, and operated from the client device), a server-based tool (e.g., installed and executed at a server that is remote from the client device, and accessed and operated by the client device), or a combination of both client-based and service-based elements.

The virtual experience development environment may be operated by a developer of a virtual experience, e.g., a game developer or any other person who seeks to create a virtual experience that may be published by an online virtual experience platform and utilized by others. The user interface of the virtual experience development environment may be rendered on a display screen of a client device, e.g., such as a developer device 130 described with reference to FIG. 1, so as to enable the creator/developer to interact with the development environment using actions such as typing, highlighting, selecting, drag and drop, clicking, and so forth via a mouse, keyboard, or other input device configured to communicate with the user interface. The user interface may include a menu bar, a tool bar, a workspace pane, and a plurality of secondary panes. Depending on the particular implementation, the user interface may include alternative or additional elements, arrangements, operational features, etc. of the virtual experience development environment than what is shown and described herein.

A developer user (creator) may utilize the virtual experience development environment to create virtual experiences. As part of the development process, the developer/creator may upload various types of digital content such as object files (meshes), image files, audio files, short videos, etc., to enhance the virtual experience.

In implementations where the 3D object is an accessory, data indicative of use of the object in a virtual experience may also be received. For example, a “shoe” object may include annotations indicating that the object can be depicted as being worn on the fect of a virtual humanoid character, while a “shirt” object may include annotations that it may be depicted as being worn on the torso of a virtual humanoid character.

In some implementations, the 3D model may further include texture information associated with the 3D object. For example, texture information may indicate color and/or pattern of an outer surface of the 3D object. The texture information may enable varying degrees of transparency, reflectiveness, degrees of diffusiveness, material properties, and refractory behavior of the textures and meshes associated with the 3D object. Examples of textures include plastic, cloth, grass, a pane of light blue glass, ice, water, concrete, brick, carpet, wood, etc.

In some implementations, the user device(s) 110 may each include computing devices such as personal computers (PCs), mobile devices (e.g., laptops, mobile phones, smart phones, tablet computers, or netbook computers), network-connected televisions, gaming consoles, etc. In some implementations, a user device 110 may also be referred to as a “client device.” In some implementations, one or more user devices 110 may connect to the online virtual experience server 102 at any given moment. It may be noted that the number of user devices 110 is provided as illustration. In some implementations, any number of user devices 110 may be used.

In some implementations, each user device 110 may include an instance of the virtual experience application 112, respectively. In one implementation, the virtual experience application 112 may permit users to use and interact with online virtual experience server 102, such as control a virtual character in a virtual game hosted by online virtual experience server 102, or view or upload content, such as virtual experiences 106, images, video items, web pages, documents, and so forth. In one example, the virtual experience application may be a web application (e.g., an application that operates in conjunction with a web browser) that can access, retrieve, present, or navigate content (e.g., virtual character in a virtual environment, etc.) served by a web server. In another example, the virtual experience application may be a native application (e.g., a mobile application, app, or a gaming program) that is installed and executes local to user device 110 and allows users to interact with online virtual experience server 102. The virtual experience application may render, display, or present the content (e.g., a web page, a media viewer) to a user. In an implementation, the virtual experience application may also include an embedded media player (e.g., a Flash® player) that is embedded in a web page.

In some implementations, the virtual experience application may include an audio engine 116 that is installed on the user device, and which enables the playback of sounds on the user device. In some implementations, audio engine 116 may act cooperatively with audio engine 144 that is installed on the sound server.

According to aspects of the disclosure, the virtual experience application may be an online virtual experience server application for users to build, create, edit, upload content to the online virtual experience server 102 as well as interact with online virtual experience server 102 (e.g., participate in virtual experiences 106 hosted by online virtual experience server 102). As such, the virtual experience application may be provided to the user device(s) 110 by the online virtual experience server 102. In another example, the virtual experience application may be an application that is downloaded from a server.

In some implementations, each developer device 130 may include an instance of the virtual experience application 132, respectively. In one implementation, the virtual experience application 132 may permit a developer user(s) to use and interact with online virtual experience server 102, such as control a virtual character in a virtual game hosted by online virtual experience server 102, or view or upload content, such as virtual experiences 106, images, video items, web pages, documents, and so forth. In one example, the virtual experience application may be a web application (e.g., an application that operates in conjunction with a web browser) that can access, retrieve, present, or navigate content (e.g., virtual character in a virtual environment, etc.) served by a web server. In another example, the virtual experience application may be a native application (e.g., a mobile application, app, or a virtual experience program) that is installed and executes local to user device 130 and allows users to interact with online virtual experience server 102. The virtual experience application may render, display, or present the content (e.g., a web page, a media viewer) to a user. In an implementation, the virtual experience application may also include an embedded media player (e.g., a Flash® player) that is embedded in a web page.

According to aspects of the disclosure, the virtual experience application 132 may be an online virtual experience server application for users to build, create, edit, upload content to the online virtual experience server 102 as well as interact with online virtual experience server 102 (e.g., provide and/or play virtual experiences 106 hosted by online virtual experience server 102). As such, the virtual experience application may be provided to the user device(s) 130 by the online virtual experience server 102. In another example, the virtual experience application 132 may be an application that is downloaded from a server. Virtual experience application 132 may be configured to interact with online virtual experience server 102 and obtain access to user credentials, user currency, etc. for one or more virtual applications 106 developed, hosted, or provided by a virtual experience application developer.

In some implementations, a user may login to online virtual experience server 102 via the virtual experience application. The user may access a user account by providing user account information (e.g., username and password) where the user account is associated with one or more characters available to participate in one or more virtual experiences 106 of online virtual experience server 102. In some implementations, with appropriate credentials, a virtual experience application developer may obtain access to virtual experience application objects, such as in-platform currency (e.g., virtual currency), avatars, special powers, accessories, which are owned by or associated with other users.

In general, functions described in one implementation as being performed by the online virtual experience server 102 can also be performed by the user device(s) 110, or a server, in other implementations if appropriate. In addition, the functionality attributed to a particular component can be performed by different or multiple components operating together. The online virtual experience server 102 can also be accessed as a service provided to other systems or devices through appropriate application programming interfaces (APIs) and thus is not limited to use in websites.

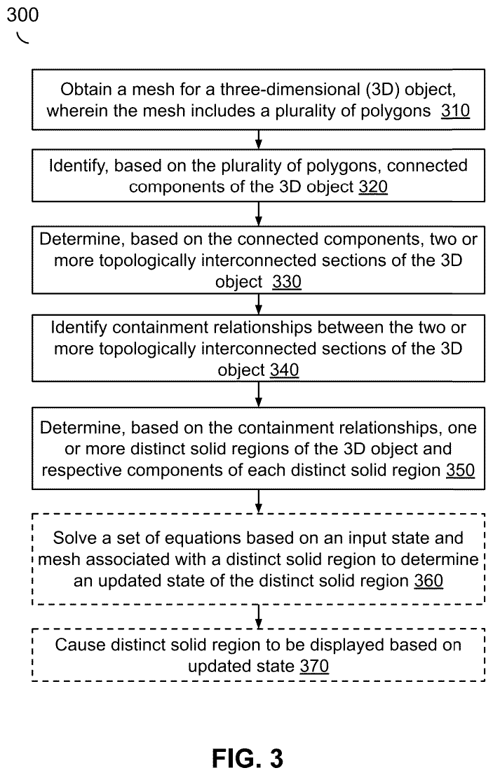

In some implementations, online virtual experience server 102 may include a graphics engine 108. In some implementations, the graphics engine 108 may be a system, application, or module that permits the online virtual experience server 102 to provide graphics and animation capability. In some implementations, the graphics engine 108, and/or content management server 140 may perform one or more of the operations described below in connection with the flowcharts and workflows shown in FIG. 3.

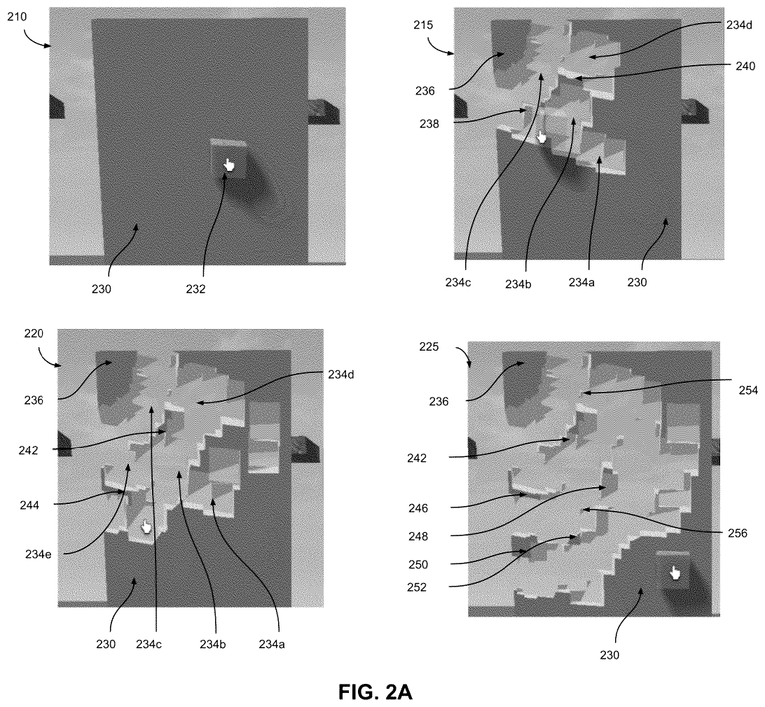

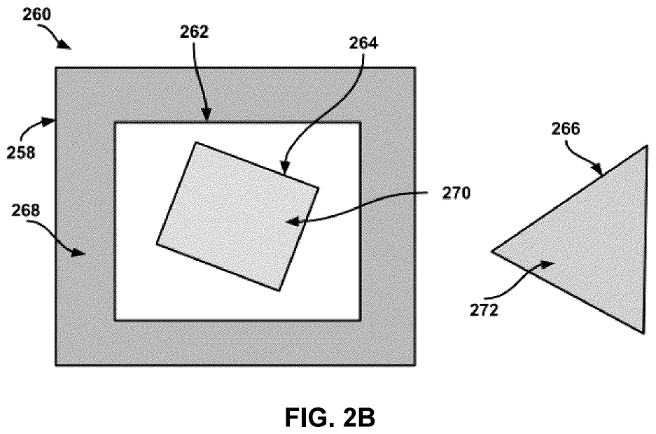

FIG. 2A illustrates example images that depict simulations of erroneously identified disconnected components of a solid body, in accordance with some implementations. FIG. 2A is a side view of a solid object.

In this illustrative example, images 210, 215, 220, and 225 depict various stages of CSG operations applied to an example solid body object 230. The CSG operations in this example include subtraction of a portion of the solid body object 230 that is indicated by a user providing a signal via cursor block 232. Explained another way, a portion of the solid body object covered by cursor block 232 is subtracted from the solid body object 230 when a user points to the portion of the solid body object 230 and provides an indicative signal, e.g., by a mouse click when hovering over a particular region of the solid body object.

In this illustrative example, the user moves the cursor block over different portions of the solid body object 230. Images 210, 215, 220, and 225 depict various stages of the user modifying an original solid body object.

Image 210 depicts an initial state that depicts the solid body object 230 without any CSG operations being applied. Images 215, 220, and 225 depict the solid body object with progressively increasing portions removed from the object via CSG operations.

For example, image 215 depicts solid body object 230, gaps 234a, 234b, 234c, and 234d that correspond to portions that were subtracted (removed) via CSG portions. Image 215 additionally depicts fragments 236, 238, and 240 (additional smaller fragments are depicted, but not numbered in FIG. 2A).

Similarly, image 220 depicts solid body object 230, gaps 234a, 234b, 234c, 234d, and 234e as well as fragments 236, 242, and 244. Image 225 depicts the solid body object 230 with additional portions removed (resulting in large gaps) and fragments 236, 242, 246, 248, 250, 252, 254, and 256.

In this example, detection of connected (and disconnected) portions of the solid body object is not performed. Consequently, the portions of the mesh of the object associated with the fragments are still considered as being connected to the original mesh. This can lead to unrealistic physical behavior, e.g., without considering the effect on gravity on the fragments, which would cause them to fall to the ground/floor (towards the bottom of the image). As can be observed in FIG. 2A, the fragments in images 215, 220, and 225 are shown in a suspended manner, and can lead to an experience that is relatively un-immersive to a user due to the lack of application of realistic physics to the individual fragments.

FIG. 2B depicts an example solid body object that is represented by a plurality of polygons, in accordance with some implementations.

In order to simplify the visualization, the solid body object is depicted here as a two-dimensional (2D) illustration, where the depicted lines represent respective polygons, and the depicted polygons in the illustration are representative of a three-dimensional (3D) mesh.

In this illustrative example, a solid body object 260 is generated based on a CSG operation is the following polygonal mesh. The solid body object 260 is represented by a 3D mesh that is defined by a set of polygons, e.g., triangles. In some implementations, the mesh is represented and/or stored as a set of triangles. (In the 2D illustration that is FIG. 2B, each triangle is depicted as a corresponding line).

For example, the solid body object 260 in FIG. 2B includes lines 258, 262, 264, and 266. Subsequent to the application of CSG operations to obtain solid body object 260, e.g., from a single original solid body object, information about whether the constituent sub-meshes constitute one single distinct solid body, or whether they constitute multiple distinct solid bodies may not be available.

For example, in this illustrative example, a 3D mesh associated with solid body object 260 includes three solid bodies, a first distinct solid body 268, a second distinct solid body 270, and a third distinct solid body 272. Due to the nature of CSG operations, what is obtained as a solid body object may include two or more disconnected bodies, as in this example. An objective of the techniques described herein is to accurately detect the set of bodies within solid body object 260 and separate them into separate polygonal meshes (sub-meshes).

FIG. 3 illustrates an example method to detect connected solid regions in a solid geometry object to be rendered on a computing device, in accordance with some implementations.

In some implementations, method 300 can be implemented, for example, on virtual experience 102 described with reference to FIG. 1. In some implementations, some or all portions of the method 300 can be implemented on one or more client devices 110 as shown in FIG. 1, on one or more developer devices 130, or on one or more server device(s) 102, and/or on a combination of developer device(s), server device(s), and client device(s). In described examples, the implementing system includes one or more digital processors or processing circuitry (“processors”), and one or more storage devices (e.g., data store 120 or other storage). In some implementations, different components of one or more servers and/or clients can perform different blocks or other parts of method 300. In some examples, a first device is described as performing blocks of method 300. Some implementations can have one or more blocks of method 300 performed by one or more other devices (e.g., other client devices or server devices) that can send results or data to the first device.

In some implementations, method 300, or portions of the method, can be initiated automatically by a system. In some implementations, the implementing system is a first device. For example, the method (or portions thereof) can be periodically performed, or performed based on one or more particular events or conditions, e.g., a request received from a user to perform method 300, receiving a 3D mesh of a 3D object generated based on a CSG operation at the virtual experience platform, a predetermined time period having expired since the last performance of method 300, and/or one or more other conditions occurring which can be specified in settings read by the method. Method 300 may begin at block 310.

At block 310, a mesh, e.g., a 3D mesh, for a three-dimensional (3D) object is obtained. In some implementations, the mesh may include a plurality of polygons, e.g., triangles, quads, etc., that are connected to form the 3D mesh. In some implementations, the quads may be divided into triangles during rendering of the 3D mesh. Each vertex of the polygon may be associated with a respective 3D coordinate.

In some implementations, at least a first polygon of the plurality of polygons is connected to a second polygon of the plurality of polygons. In some implementations, the plurality of polygons, e.g., triangles, is generated by application of one or more CSG operations to a CSG representation of an original solid body (3D) object.

In some implementations, the 3D mesh may be obtained as a list of polygons, e.g., a list of triangles, where each triangle is defined by its respective vertices. In some implementations, the mesh may be received (imported) in an FBX file format. The mesh file may include data that provides dimensional data about polygons that comprise the solid body object and UV map data that is descriptive of the attachment relationship between various portions of texture and various polygons that comprise the solid body object.

UV mapping is the 3D modeling process of projecting a 2D image to a 3D model's surface for texture mapping. The letters “U” and “V” can denote the axes of the 2D texture where “X,” “Y,” and “Z” denote the axes of the 3D object in model space. Vertices may be assigned UV coordinates by tracing which pixels in the depth image project down to which vertices in the 3D model. These coordinates may indicate the pixel location in the texture image to which a vertex corresponds. For example, if the texture image is of size (256, 512) and a vertex projects onto the pixel at (112, 234), the UV coordinates for that vertex are (112/256, 234/512)=(0.4375, 0.457).

In some implementations, the 3D object may correspond to an accessory, e.g., a hat, a weapon, a piece of clothing, etc. worn by a virtual avatar or otherwise depicted with reference to a virtual avatar. In some other implementations, the 3D object may be a building or other structure, e.g., a castle, designed to be used within the virtual experience. Block 310 may be followed by block 320.

At block 320, connected components of the 3D object are identified based on the plurality of polygons. For example, the connected components of the 3D object may be identified based on the connectivity of respective polygons of the plurality of polygons.

In some implementations, a union set data structure may be utilized to identify connected regions in a mesh of the 3D object. In some implementations, identifying the connected components may include performing mesh traversal of the mesh along polygon edges of the plurality of polygons to identify individual components of the 3D object, wherein the mesh traversal is performed by a breadth-first search (BFS) or a depth-first search (DFS), which may be provide improved cache coherence and superior performance.

Block 320 may be followed by block 330.

At block 330, two or more topologically interconnected sections of the 3D object are determined based on the connected components. In some implementations, the determination of the two or more topologically interconnected sections of the 3D object may include leveraging a disjoint set data structure to pinpoint the distinct topologically interconnected sections within the mesh.

In some implementations, the determination of the two or more topologically interconnected sections of the 3D object may include applying techniques that include guarantees for the connectivity of its outputs (e.g., a 3D mesh). In some implementations, method 300 may include applying a union by rank and/or a path compression technique.

In some implementations, subsequent to the determination (identification) of connected components, the identified connected components (e.g., the vertices of the polygons associated with the identified connected components) may be stored in a disjoint-set data structure.

In some implementations, method 300 may further include determining whether each of the topologically interconnected sections (shells) is an inner shell or an outer shell. In some implementations, determining whether each of the topologically interconnected sections is an inner shell or an outer shell may include determining a sign of an oriented volume of a topologically interconnected section.

In some implementations, determining whether each of the topologically interconnected sections is an inner shell or an outer shell may include determining a direction of a normal corresponding to each topologically interconnected section. For example, a direction of a normal may be determined with respect to one or more surfaces of a topologically interconnected section.

A topologically interconnected section (shell) is considered to be an inner shell if it has an inward pointing normal considered to be an outer shell if it has an outward pointing normal. In some implementations, the direction of a normal corresponding to a surface of each topologically interconnected section may be obtained automatically, along with the 3D mesh, e.g., where a normal is already determined for each polygon and is provided along with the polygons associated with a 3D mesh.

In some implementations, whether a shell is an inner shell or an outer shell may be determined by applying a signed volume formula, e.g., determining a volume of a polygonal mesh and an associated sign.

For example, where the mesh is based on a set of triangles, a determinant of each triangle that makes up the mesh is calculated, and a sum of all the determinants calculated. A negative value for the sum of all determinants is indicative of the mesh representing an inner shell, and a positive value for the sum of all determinants is indicative of the mesh representing an outer shell.

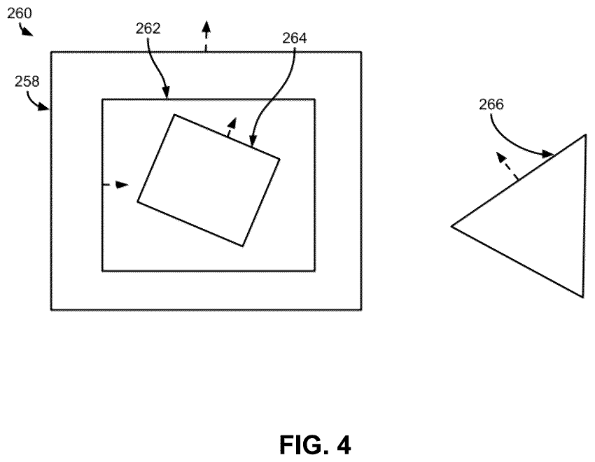

FIG. 4 illustrates determination of whether a topologically interconnected section is an inner shell or an outer shell, in accordance with some implementations.

As depicted in FIG. 4, the surfaces of polygon 258, polygon 266, and polygon 264 have outward pointing normals, while the surface of polygon 262 has inward pointing normals. Accordingly, in this illustrative example, polygons 258, 266, and 264 are outer shells, while polygon 262 is an inner shell.

In some scenarios, determination of a type of shell (whether inner shell or outer shell) for each of the topologically connected sections may be sufficient to detect distinct solid regions. For example, in a scenario where each of the topologically interconnected sections is determined to be an outer shell, it may be determined, in response to determination that each of the topologically interconnected sections is an outer shell, that each of the topologically interconnected sections is a distinct solid region distinct from other topologically interconnected sections.

In other words, if all the shells are outer shells, then it may be determined (concluded) that each outer shell represents a filled solid body (since there are no inner shells). An early determination that all the shells included in the obtained 3D object are outer shells may enable an early termination of method 300, and a determination of all included distinct solid objects within the original 3D mesh.

Block 330 may be followed by block 340.

At block 340, a containment relationship may be identified between the two or more topologically interconnected sections of the 3D object. For example, if it is determined that there is at least one inner shell included in the obtained mesh, the correspondence (containment relationship) of the at least one inner shell with outer shells included in the 3D mesh is determined. In some implementations, the containment relationship between an inner shell and one or more outer shells may be based on a relationship (whether a shell is completed contained within another) between their corresponding bounding boxes. In some implementations, method 300 may include calculating a bounding box for each of the identified connected components (inner shells and outer shells).

In some implementations, a bounding box of a solid body object (represented by its 3D mesh) is a simple geometric body that can contain the solid body object and form a conservative estimation of the boundaries of the solid body object, thus enabling the replacement of the solid body object by the simple geometric body for computational purposes.

In different implementations, various types of bounding boxes may be utilized, e.g., axis-aligned bounding box (AABB), a spherical bounding box, oriented bounding box (OBB), fixed direction hull, etc. In some implementations, the bounding box may be utilized to perform tests that may be used to speed up ray intersection tests utilized to determine containment.

In some implementations, method 300 may include determining a containment relationship between a first topologically interconnected section and a second topologically interconnected section based on a relationship between a first bounding box that corresponds to the first topologically interconnected section and a second bounding box that corresponds to the second topologically interconnected section.

For example, a containment relationship between a first topologically interconnected section and a second topologically interconnected section may be determined based on a determination that a first bounding box that corresponds to the first topologically interconnected section is entirely contained within a second bounding box that corresponds to the second topologically interconnected section.

Subsequent to determining bounding boxes for each shell, bounding box filtering may be utilized to determine containment relationships between the shells.

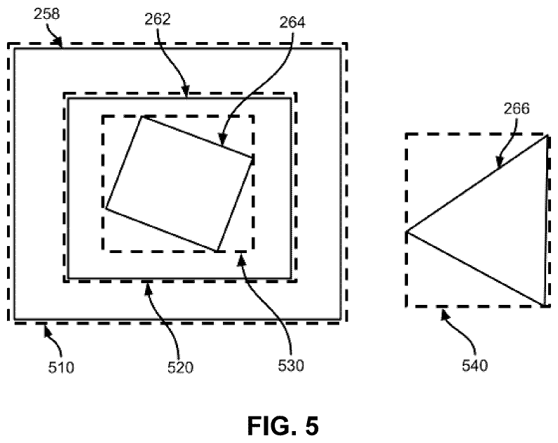

FIG. 5 depicts bounding box filtering to determine containment relationships between respective inner shells and outer shells, in accordance with some implementations.

In this illustrative example, polygon 258 has a corresponding bounding box 510, polygon 262 has a corresponding bounding box 520, polygon 264 has a corresponding bounding box 530, and polygon 266 has a corresponding bounding box 540.

In some scenarios, early termination of method 300 may be performed, e.g., at block 330 or block 340, based on the containment relationships. For example, in some implementations, where a first topologically interconnected section is an inner shell that is enclosed only by the second topologically interconnected section that is an outer shell, method 300 may include determining that the first topologically interconnected section and the second topologically interconnected section correspond to a same distinct solid region.

In this illustrative example, there is only one bounding box 520 (corresponding to polygon 262) that is enclosed by only one outer shell bounding box 510 (corresponding to polygon 258). Accordingly, a determination may be made that polygon 258 and polygon 262 are part of a same distinct body. Additionally, it may be determined that polygon 264 and polygon 266 are separate distinct solid bodies (since they are outer shells that have no associated inner shells). Block 340 may be followed by block 350.

At block 350, one or more distinct solid regions of the 3D object may be determined based on the containment relationship between the boundary boxes of respective shells. In some implementations, a first distinct solid region is detected based on identifying a first outer shell that contains a first inner shell.

In some implementations, determining the outermost component corresponding to the inner shell may be based on a respective winding number of the connected components of the 3D object. In some implementations, for each inner shell, winding numbers associated with one or more outer shells may be evaluated to determine which of the bounding boxes of one or more outer shells encloses the bounding box of the inner shell. In some implementations, evaluation of the bounding boxes of the outer shells is based on a determination of a winding number of each outer shell bounding box with respect to a point on the inner shell.

The winding number (also referred to as a winding index) of an outer shell around a given point on an inner shell is an integer that represents the total number of times that the outer shell travels counterclockwise around the point on the inner shell. In some implementations, subsequent to determination of the winding numbers of a plurality of outer shells, method 300 may include recursively selecting an outermost component and utilizing the winding number to determine all other components that belong to the same solid region.

In some implementations, the recursive selection may be performed as follows:

Step 1: An outermost component is selected based on bounding box size as an outer shell.

Step 2: A set, S, of all components that are contained within the outer component is determined (computer) based on a winding number of each component with respect to the outer shell.

Step 3: Based on the winding numbers, components in S that are nested within another component in S are removed.

Step 4: The outer shell and all remaining components in S are combined into a single solid component.

Step 5: All components that have been combined into a single solid component are removed from the set of components and the process goes back to Step 1 (Until all outer components are handled).

In some implementations, when an inner shell is determined to be contained by two or more outer shells, an outer shell that is closest to the inner shell is determined to be the corresponding outer shell. For example, in some implementations, identifying the first outer shell that contains the first inner shell may include finding an outer shell that is closest to the inner shell, and wherein the outer shell has a winding number of +1 relative to the inner shell.

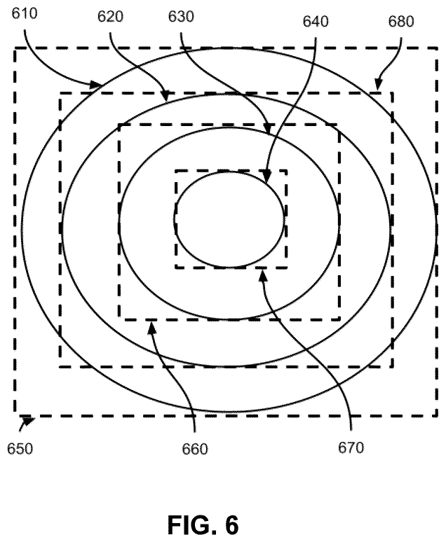

FIG. 6 depicts an example of two solid bodies that are composed of two inner shells and two outer shells, in accordance with some implementations.

In this illustrative example, FIG. 6 depicts an inner shell 620 with bounding box 680 and inner shell 640 with bounding box 670 that is enclosed by a first outer shell 630 with bounding box 660 and a second outer shell 610 with bounding box 650.

Since the bounding box of the smallest inner shell 640 is enclosed by the bounding boxes of both outer shells (second outer shell 610 and first outer shell 630), a winding number test is performed to determine a containment relationship between the inner shell 640 and the two outer shells.

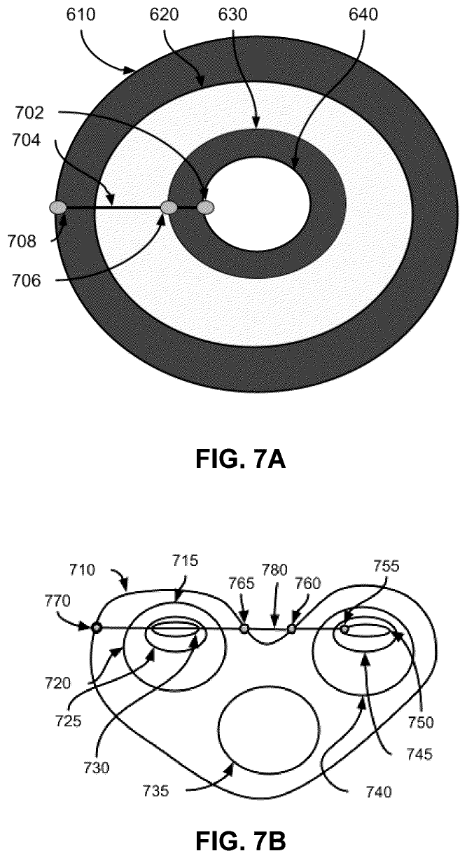

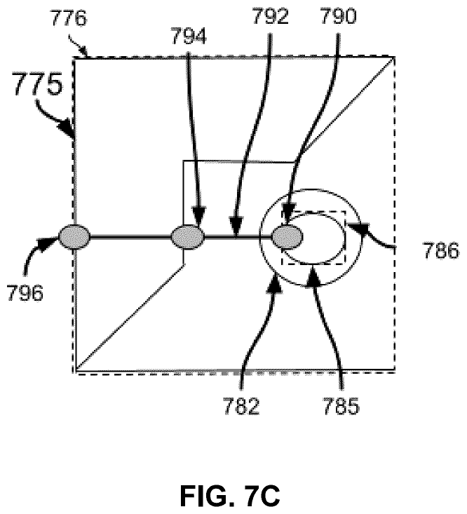

FIG. 7A depicts an example of determination of an outer shell that corresponds to a particular inner shell based on a winding number test, in accordance with some implementations.

A left-most point 702 on inner shell 640 is identified, and a beam 704 (ray) is extended towards the left such that it intersects first outer shell 630 at point 706 and second outer shell 610 at point 708. In this illustrative example, both outer shells (first outer shell 630 and second outer shell 610) have a winding number of +1 relative to point 702. Accordingly, outer shell 630 (since it lies at a smaller distance to inner shell 640 when compared to outer shell 610) is selected to be in the body with inner shell 640.

In some implementations, a leftmost point is identified as the point with a lowest (minimal) x coordinate. In some implementations, extending a ray leftwards may include shooting a ray into the negative x direction and finding all intersection points.

FIG. 7B depicts another example of determination of an outer shell that corresponds to a particular inner shell based on a winding number test, in accordance with some implementations.

In this illustrative example, a heart-shaped outer shell 710 appears to contain inner shell 720, inner shell 740, inner shell 735, and inner shell 740. Inner shell 720 contains an outer shell 725 and inner shell 730. Inner shell 740 contains an outer shell 745 and inner shell 750.

In this scenario, the winding number of the heart-shaped outer shell 710 with respect to point 755 on inner shell 750 is +1, which is the sum of the winding numbers of the intersecting points 760, 765, and 770 located along beam 780. Accordingly, inner shell 750 is associated with outer shell 745 (since it lies closest and has winding number +1).

FIG. 7C depicts another example of determination of an outer shell that corresponds to a particular inner shell based on a winding number test, in accordance with some implementations.

FIG. 7C depicts an outer shell 775 with a bounding box 776, an inner shell 785 with bounding box 786, and outer shell 782. A determination of a winding number of bounding box 776 with respect to bounding box 786 is determined by extending beam 792 leftwards from point 790 with intersecting points 794 and 796.

In this illustrative example, even though bounding box 776 corresponding to outer shell 775 contains the inner shell bounding box 786, the inner shell 785 is determined to lie outside outer shell 775 since the effective winding number of the bounding box 776 with respect to point 790 is 0.

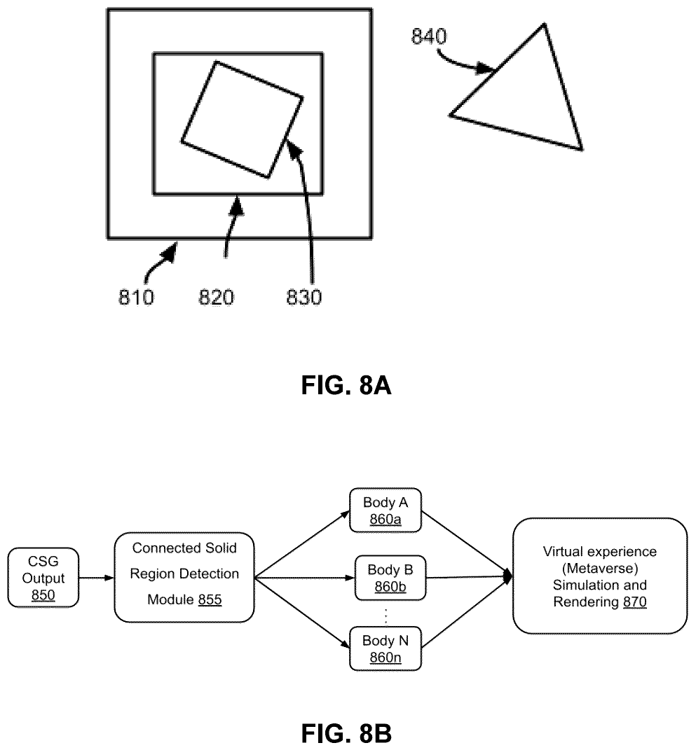

FIG. 8A depicts detection of connected solid regions in an example solid geometry object, in accordance with some implementations.

In this illustrative example (that corresponds to the solid body object 260 and corresponding 3D mesh described with reference to FIG. 2B, by implementing method 300 described herein, it is determined that shell 810 and shell 820 represent a single distinct solid object (region), while shell 830 and shell 840 are separate distinct solid objects.

FIG. 8B depicts an example workflow to provide a virtual experience simulation engine with a set of disconnected solid regions based on a solid body object generated from performing constructive solid geometry (CSG) operations, in accordance with some implementations.

As illustrated in FIG. 8B, an output of CSG operation(s) is received at block 850 and provided to connected solid region detection module 855. Based on applying techniques described herein, e.g., one or more blocks of method 300, a received 3D mesh is separated into distinct solid bodies, Body A 860a, Body B 860b, and Body N 860n, each represented by a corresponding sub-mesh. The distinct solid bodies (and/or sub-meshes) may be provided to downstream virtual experience simulation and rendering modules 870 for utilization in a virtual experience and/or virtual experience platform.

For example, identifying information of a first distinct solid region of the one or more distinct solid regions of the 3D object and a first sub-mesh associated with the first distinct solid region may be provided to a physics engine (physics solver).

Block 350 may be followed by block 360. At block 360, a set of equations may be solved based on an input state and the first sub-mesh associated with the first distinct solid region to determine an updated state of the first distinct solid region of the 3D object, wherein the updated state includes an updated position of the first distinct solid region, an updated orientation of the first distinct solid region, or a combination thereof.

In some implementations, motion of the first distinct solid region in a virtual environment may be simulated by providing to a physics solver the following-a current or input state of the first distinct solid region, constraints associated with the first distinct solid region, and one or more forces acting on the first distinct solid region to determine an updated state of the first distinct solid region.

The input state of the first distinct solid region may either be an initial state, e.g., at the start/commencement of a simulation, or a previous first distinct solid region state from a previously determined state. For example, an input state may be an initial state of a vehicle in a virtual environment, just before the vehicle starts moving.

Inputs to the physics solver may further include external force(s) that act on the first distinct solid region within the virtual environment, e.g., a gravitational force that is acting on a falling object. The external force(s) may be a default setting within the environment, user defined settings, or a combination. For example, a user may specify a gravity-free setting for a virtual environment, which results in simulation of a gravity-free virtual environment, e.g., gravitational forces would not be applied on the first distinct solid region. Block 360 may be followed by block 370.

At block 370, the first distinct solid region of the 3D object in the updated state may be caused to be displayed, e.g., within a virtual environment or any other environment in which the 3D object can be viewed.

In some implementations, the first distinct solid region may be displayed, e.g., on a display screen, based on the determined updated state. The updated velocity, orientation, and/or position of the first distinct solid region may be utilized for animation and determining images (frames) of the virtual environment that depict a state and motion of the first distinct solid region in the virtual environment. A similar process may be followed for other distinct solid regions determined by method 300.

Method 300, or portions thereof, may be repeated any number of times using additional inputs. Blocks 310-370 may be performed (or repeated) in a different order than described above and/or one or more steps can be omitted. For example, blocks 360-370 may be omitted in some implementations.

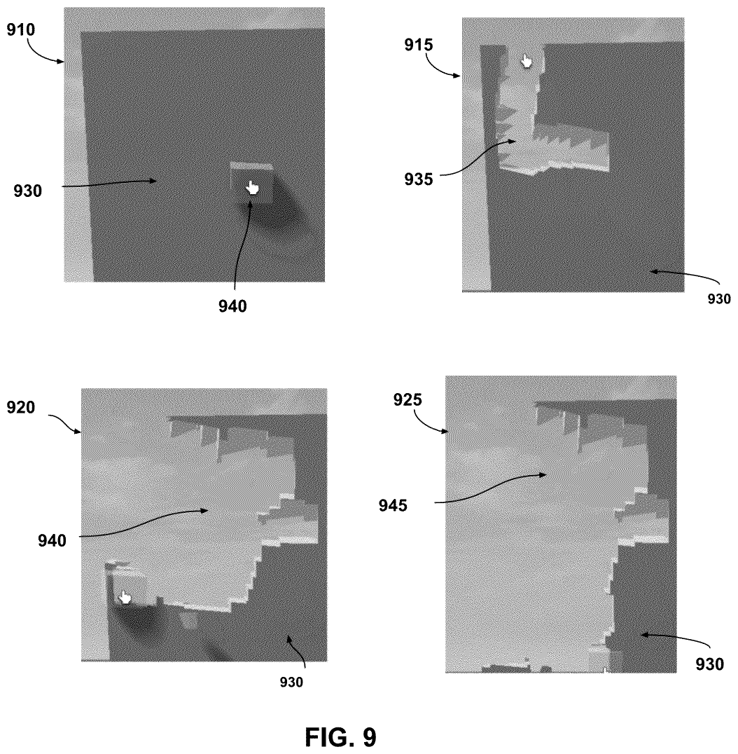

FIG. 9 illustrates example images that depict simulations that include correctly identified disconnected components of a solid body, in accordance with some implementations.

In this illustrative example that corresponds to the example described with reference to FIG. 2A, techniques described herein are applied to an example solid body object 930. Images 910, 915, 920, and 925 depict various stages of CSG operations applied to solid body object 930. The CSG operations in this example include a subtraction of a portion of the solid body object 930 that is indicated by a user providing a signal via cursor block 940.

As can be observed in FIG. 9 (and particularly in contrast with FIG. 2A), any generated fragments are detected as disconnected solid bodies and the output from the CSG operations is divided into several separately simulated (distinct) 3D objects that can collide and be influenced by gravity. Accordingly, images 910, 915, 920, and 925 are more accurate representation of physical behavior and provide for a more immersive (and accurate) user experience.

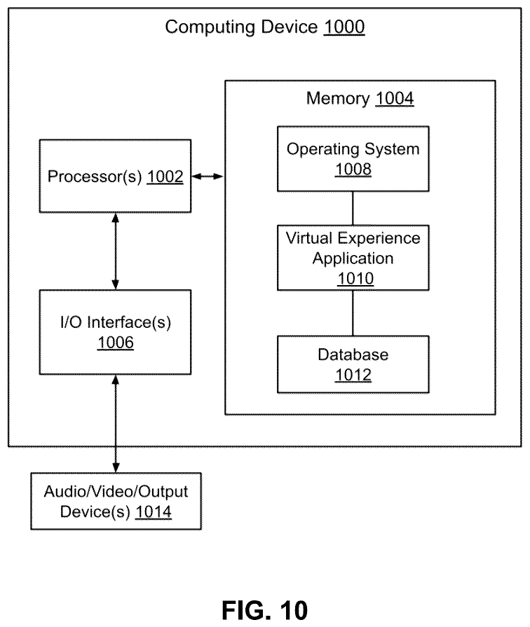

FIG. 10 illustrates an example computing device, in accordance with some implementations.

In one example, device 1000 may be used to implement a computer device (e.g., 102, 110, and/or 130 of FIG. 1), and perform suitable method implementations described herein. Computing device 1000 can be any suitable computer system, server, or other electronic or hardware device. For example, the computing device 1000 can be a mainframe computer, desktop computer, workstation, portable computer, or electronic device (portable device, mobile device, cell phone, smartphone, tablet computer, television, TV set top box, personal digital assistant (PDA), media player, game device, wearable device, etc.). In some implementations, device 1000 includes a processor 1002, a memory 1004, input/output (I/O) interface 1006, and audio/video input/output devices 1014.

Processor 1002 can be one or more processors, processing devices, and/or processing circuits to execute program code and control basic operations of the device 1000. A “processor” includes any suitable hardware and/or software system, mechanism or component that processes data, signals or other information. A processor may include a system with a general-purpose central processing unit (CPU), multiple processing units, dedicated circuitry for achieving functionality, or other systems. Processing need not be limited to a particular geographic location or have temporal limitations. For example, a processor may perform its functions in “real-time,” “offline,” in a “batch mode,” etc. Portions of processing may be performed at different times and at different locations, by different (or the same) processing systems. A computer may be any processor in communication with a memory.

Memory 1004 is typically provided in device 1000 for access by processor 1002 and may be any suitable processor-readable storage medium, e.g., random access memory (RAM), read-only memory (ROM), Electrical Erasable Read-only Memory (EEPROM), Flash memory, etc., suitable for storing instructions for execution by the processor, and located separate from processor 1002 and/or integrated therewith. Memory 1004 can store software operating on the server device 1000 by the processor 1002, including an operating system 1008, one or more applications 1010, e.g., a virtual experience application, a sound application, content management application, and application data included in database 1012. In some implementations, virtual experience application 1010 can include instructions that enable processor 1002 to perform the functions (or control the functions of) described herein, e.g., some or all of the methods described with respect to FIG. 3.

For example, virtual experience application 1010 can include an audio spatialization module which as described herein can provide audio spatialization within an online virtual experience server (e.g., 102). Any software in memory 1004 can alternatively be stored on any other suitable storage location or computer-readable medium. In addition, memory 1004 (and/or other connected storage device(s)) can store instructions and data used in the features described herein. Memory 1004 and any other type of storage (magnetic disk, optical disk, magnetic tape, or other tangible media) can be considered “storage” or “storage devices.”

I/O interface 1006 can provide functions to enable interfacing the server device 1000 with other systems and devices. For example, network communication devices, storage devices (e.g., memory and/or data store 120), and input/output devices can communicate via interface 1006. In some implementations, the I/O interface can connect to interface devices including input devices (keyboard, pointing device, touchscreen, microphone, camera, scanner, etc.) and/or output devices (display device, speaker devices, printer, motor, etc.).

The audio/video input/output devices 1014 can include a user input device (e.g., a mouse, etc.) that can be used to receive user input, a display device (e.g., screen, monitor, etc.) and/or a combined input and display device, that can be used to provide graphical and/or visual output.

For case of illustration, FIG. 10 shows one block that is representative of each processor 1002, memory 1004, I/O interface 1006, and software blocks that include operating system 1008 and virtual experience application 1010. These blocks may represent one or more processors, computing instances on distributed computing systems, processing devices, or processing circuitries, operating systems, memories, I/O interfaces, applications, and/or software engines. In other implementations, device 1000 may not have all of the components shown and/or may have other elements including other types of elements instead of, or in addition to, those shown herein. While the online virtual experience server 102 is described as performing operations as described in some implementations herein, any suitable component or combination of components of online virtual experience server 102 or similar system, or any suitable processor or processors associated with such a system, may perform the operations described.

A user device can also implement and/or be used with features described herein. Example user devices can be computer devices including some similar components as the device 1000, e.g., processor(s) 1002, memory 1004, and I/O interface 1006. An operating system, software and applications suitable for the user device can be provided in memory and used by the processor. The I/O interface for a user device can be connected to network communication devices, as well as to input and output devices, e.g., a microphone for capturing sound, a camera for capturing images or video, a mouse for capturing user input, a gesture device for recognizing a user gesture, a touchscreen to detect user input, audio speaker devices for outputting sound, a display device for outputting images or video, or other output devices. A display device within the audio/video input/output devices 1014, for example, can be connected to (or included in) the device 1000 to display images pre- and post-processing as described herein, where such display device can include any suitable display device, e.g., an LCD, LED, or plasma display screen, CRT, television, monitor, touchscreen, 3-D display screen, projector, or other visual display device. Some implementations can provide an audio output device, e.g., voice output or synthesis that speaks text.

One or more methods described herein (e.g., method 300, etc.) can be implemented by computer program instructions or code, which can be executed on a computer. For example, the code can be implemented by one or more digital processors (e.g., microprocessors or other processing circuitry), and can be stored on a computer program product including a non-transitory computer-readable medium (e.g., storage medium), e.g., a magnetic, optical, electromagnetic, or semiconductor storage medium, including semiconductor or solid state memory, magnetic tape, a removable computer diskette, a random access memory (RAM), a read-only memory (ROM), flash memory, a rigid magnetic disk, an optical disk, a solid-state memory drive, etc. The program instructions can also be contained in, and provided as, an electronic signal, for example in the form of software as a service (SaaS) delivered from a server (e.g., a distributed system and/or a cloud computing system). Alternatively, one or more methods can be implemented in hardware (logic gates, etc.), or in a combination of hardware and software. Example hardware can be programmable processors (e.g., Field-Programmable Gate Array (FPGA), Complex Programmable Logic Device), general purpose processors, graphics processors, Application Specific Integrated Circuits (ASICs), and the like. One or more methods can be performed as part of or component of an application running on the system, or as an application or software running in conjunction with other applications and operating systems.

One or more methods described herein can be run in a standalone program that can be run on any type of computing device, a program run on a web browser, a mobile application (“app”) run on a mobile computing device (e.g., cell phone, smart phone, tablet computer, wearable device (wristwatch, armband, jewelry, headwear, goggles, glasses, etc.), laptop computer, etc.). In one example, a client/server architecture can be used, e.g., a mobile computing device (as a user device) sends user input data to a server device and receives from the server the final output data for output (e.g., for display). In another example, all computations can be performed within the mobile app (and/or other apps) on the mobile computing device. In another example, computations can be split between the mobile computing device and one or more server devices.

Although the description has been described with respect to particular implementations thereof, these particular implementations are merely illustrative, and not restrictive. Concepts illustrated in the examples may be applied to other examples and implementations.

Note that the functional blocks, operations, features, methods, devices, and systems described in the present disclosure may be integrated or divided into different combinations of systems, devices, and functional blocks as would be known to those skilled in the art. Any suitable programming language and programming techniques may be used to implement the routines of particular implementations. Different programming techniques may be employed, e.g., procedural or object-oriented. The routines may execute on a single processing device or multiple processors. Although the steps, operations, or computations may be presented in a specific order, the order may be changed in different particular implementations. In some implementations, multiple steps or operations shown as sequential in this specification may be performed at the same time.

What is claimed is:

1. A computer-implemented method, comprising:
obtaining a mesh for a three-dimensional (3D) object, wherein the mesh includes a plurality of polygons;
identifying, based on the plurality of polygons, connected components of the 3D object;
determining, based on the connected components, two or more topologically interconnected sections of the 3D object;
identifying a containment relationship between the two or more topologically interconnected sections of the 3D object; and
determining, based on the containment relationship, one or more distinct solid regions of the 3D object.

2. The computer-implemented method of claim 1, wherein identifying the connected components comprises performing mesh traversal of the mesh along polygon edges of the plurality of polygons to identify individual components of the 3D object, wherein the mesh traversal is performed by a breadth-first search (BFS) or a depth-first search (DFS).

3. The computer-implemented method of claim 1, further comprising storing the connected components in a disjoint-set data structure.

4. The computer-implemented method of claim 1, further comprising determining whether each of the topologically interconnected sections is an inner shell or an outer shell.

5. The computer-implemented method of claim 4, wherein determining whether each of the topologically interconnected sections is an inner shell or an outer shell comprises determining a sign of an oriented volume corresponding to each topologically interconnected section.

6. The computer-implemented method of claim 4, wherein each of the topologically interconnected sections is determined to be an outer shell, and wherein the method further comprises determining, in response to determination that each of the topologically interconnected sections is an outer shell, that each of the topologically interconnected sections is a distinct solid region distinct from other topologically interconnected sections.

7. The computer-implemented method of claim 4, further comprising determining a containment relationship between a first topologically interconnected section and a second topologically interconnected section based on a determination that a first bounding box that corresponds to the first topologically interconnected section is entirely contained within a second bounding box that corresponds to the second topologically interconnected section.

8. The computer-implemented method of claim 7, wherein the first topologically interconnected section is an inner shell that is enclosed only by the second topologically interconnected section that is an outer shell, and wherein the method comprises determining that the first topologically interconnected section and the second topologically interconnected section correspond to a same distinct solid region.

9. The computer-implemented method of claim 4, further comprising detecting a first distinct solid region based on identifying a first outer shell that contains a first inner shell.

10. The computer-implemented method of claim 9, wherein identifying the first outer shell that contains the first inner shell comprises finding an outer shell that is closest to the inner shell, and wherein the outer shell has a winding number of +1 relative to the inner shell.

11. The computer-implemented method of claim 1, further comprising:
providing identifying information of a first distinct solid region of the one or more distinct solid regions of the 3D object and a first sub-mesh associated with the first distinct solid region to a physics engine;
determining an input state of the first distinct solid region of the 3D object, wherein the input state comprises a position associated with the first distinct solid region of the 3D object, an orientation associated with the first distinct solid region of the 3D object, or a combination thereof;
solving, by the physics engine, a set of equations based on the input state and the first sub-mesh associated with the first distinct solid region to determine an updated state of the first distinct solid region of the 3D object, wherein the updated state includes an updated position, an updated orientation, or a combination thereof; and
causing the first distinct solid region of the 3D object in the updated state to be displayed.

12. A non-transitory computer-readable medium with instructions stored thereon that, responsive to execution by a processing device, cause the processing device to perform operations comprising:
obtaining a mesh for a three-dimensional (3D) object, wherein the mesh includes a plurality of polygons;
identifying, based on the plurality of polygons, connected components of the 3D object;
determining, based on the connected components, two or more topologically interconnected sections of the 3D object;
identifying a containment relationship between the two or more topologically interconnected sections of the 3D object; and
determining, based on the containment relationship, one or more distinct solid regions of the 3D object.

13. The non-transitory computer-readable medium of claim 12, wherein identifying the connected components comprises performing mesh traversal of the mesh along polygon edges of the plurality of polygons to identify individual components of the 3D object, wherein the mesh traversal is performed by a breadth-first search (BFS) or a depth-first search (DFS).

14. The non-transitory computer-readable medium of claim 12, wherein the operations further comprise determining whether each of the topologically interconnected sections is an inner shell or an outer shell.

15. The non-transitory computer-readable medium of claim 14, wherein determining whether each of the topologically interconnected sections is an inner shell or an outer shell comprises determining a sign of an oriented volume corresponding to each topologically interconnected section.

16. A system comprising:
a memory with instructions stored thereon; and
a processing device, coupled to the memory, the processing device configured to access the memory and execute the instructions, wherein the instructions cause the processing device to perform operations comprising:
obtaining a mesh for a three-dimensional (3D) object, wherein the mesh includes a plurality of polygons;
identifying, based on the plurality of polygons, connected components of the 3D object;
determining, based on the connected components, two or more topologically interconnected sections of the 3D object;
identifying a containment relationship between the two or more topologically interconnected sections of the 3D object; and
determining, based on the containment relationship, one or more distinct solid regions of the 3D object.

17. The system of claim 16, wherein the operations further comprise determining whether each of the topologically interconnected sections is an inner shell or an outer shell.

18. The system of claim 16, wherein the operations further comprise further comprising detecting a first distinct solid region based on identifying a first outer shell that contains a first inner shell.

19. The system of claim 18, wherein identifying the first outer shell that contains the first inner shell comprises finding an outer shell that is closest to the inner shell, and wherein the outer shell has a winding number of +1 relative to the inner shell.

20. The system of claim 16, wherein the operations further comprise:
providing identifying information of a first distinct solid region of the one or more distinct solid regions of the 3D object and a first sub-mesh associated with the first distinct solid region to a physics engine;
determining an input state of the first distinct solid region of the 3D object, wherein the input state comprises a position associated with the first distinct solid region of the 3D object, an orientation associated with the first distinct solid region of the 3D object, or a combination thereof;
solving, by the physics engine, a set of equations based on the input state and the first sub-mesh associated with the first distinct solid region to determine an updated state of the first distinct solid region of the 3D object, wherein the updated state includes an updated position, an updated orientation, or a combination thereof; and
causing the first distinct solid region of the 3D object in the updated state to be displayed.
